(19) United States
(12) Patent Application Publication
(10) Pub. No.: US 2007/0194402 A1
(43) Pub. Date: Aug. 23, 2007

(54) Shallow trench isolation structure

(75) Inventors: Sukesh Sandhu, Boise, ID (US); Xiaolong Fang, Boise, ID (US)

Correspondence Address: BROOKS, CAMERON & HUEBSH , PLLC, 1221 NICOLLET AVENUE , SUITE 500, MINNEAPOLIS, MN, 55403, US

(73) Assignee: Micron Technology, Inc.

(21) Appl. No.: 11/358,267

(22) Filed: Feb. 21, 2006

(51) Int. Cl. H01L 29/00

(52) U.S. Cl. 257/506

(57) ABSTRACT

Structures, methods, devices, and systems are provided, including shallow trench isolation structures. In particular, a semiconductor device including a substrate and a shallow trench isolation structure on the substrate. The shallow trench isolation structure includes a first isolation trench portion and a second isolation trench portion. The first isolation trench portion has a first sidewall that is perpendicular or nearly perpendicular to the surface of the substrate, while the second isolation trench portion has a second sidewall that is angled obliquely with respect to the surface of the substrate. The second isolation trench portion is formed such that it has a smaller volume than the first isolation trench portion.

### TECHNICAL FIELD

The present invention relates to the field of semiconductor integrated circuits and, in particular, to an improved structure and method for making shallow trenches for isolation.

### BACKGROUND OF THE INVENTION

In modern semiconductor device applications, numerous devices are packed onto a single small area of a semiconductor substrate to create an integrated, circuit. For the circuit to function, many of these individual devices may need to be electrically isolated from one another. Accordingly, electrical isolation is an important and integral part of semiconductor device design for preventing the unwanted electrical coupling between adjacent components and devices.

As the size of integrated circuits is reduced, the devices that make up the circuits must be positioned closer together in order to comply with the limited space available on a typical semiconductor substrate. As the industry strives towards a greater density of active components per unit area of semiconductor substrate, effective isolation between circuits becomes all the more important.

The conventional method of isolating circuit components in modem integrated circuit technology takes the form of trench isolation regions etched into a semiconductor substrate. Trench isolation regions are commonly divided into three categories: shallow trenches (STI) (trenches less than about 1 micron deep); moderate depth trenches (trenches of from about 1 to about 3 microns deep); and deep trenches (trenches greater than about 3 microns deep). Once the trench isolation regions are etched in the semiconductor substrate, a dielectric material is deposited to fill the trenches. As the density of components on the semiconductor substrate increased, the widths of the trenches decreased until the process of flowing dielectric material into the trenches developed problems.

Trench isolation regions, particularly STI regions, can develop undesirable voids in the dielectric material during the process to fill the trenches. As the dielectric material flows to an edge between a substrate surface and a sidewall of the trench, constrictions develop at the top of trenches due to the narrow opening in the trench. As the dielectric material flows into the trench, the constrictions can develop into voids moving into the trench with the dielectric material. Once the voids are formed, a later etch-back, for example an oxide etch, could expose voids formed near the surface of the substrate. The exposed voids, consequently, may then be filled or contaminated with conductive materials, which would lower the dielectric characteristics of the dielectric material used and introduce structural instabilities in subsequent processes. Accordingly, voids in the dielectric material filling an isolation trench region are highly undesirable.

### SUMMARY OF THE INVENTION

The present disclosure provides an improved shallow trench isolation structure. In one embodiment, the shallow trench isolation structure has a first and a second isolation trench portion within a substrate. The first isolation trench portion has a first sidewall that is perpendicular or nearly perpendicular to the surface of the substrate. The second isolation trench portion has a second sidewall that is angled obliquely with respect to the surface of the substrate. Also, the volume of the second isolation trench portion is smaller than the volume of the first isolation trench portion. In another embodiment, the second sidewall tapers to a rounded point in the center of the shallow trench isolation structure. The shallow trench isolation structure is then filled with a dielectric. The improved shallow trench isolation structure reduces the formation of voids in the dielectric fill process.

In another embodiment, a trench isolation structure is formed in a semiconductor including a first isolation trench portion having a first sidewall intersecting a surface of the semiconductor at a first angle of approximately ninety (90) degrees. The structure also includes a second isolation trench portion within and extending below the first isolation trench portion, including a second sidewall intersecting the first sidewall at a second angle with respect to the surface of the semiconductor that is less than the first angle. In one embodiment, the second angle ranges from approximately fifty (50) degrees to approximately eighty-five (85) degrees. In an additional embodiment, the first isolation trench portion has a first depth ranging from about twenty (20) percent to about fifty (50) percent of the total trench depth of the trench isolation structure. In yet another embodiment, the first depth ranges from approximately five hundred (500) to approximately one thousand (1,000) angstroms (Å), and the total trench depth ranges from approximately two thousand (2,000) to approximately two thousand five hundred (2,500) Å. In still another embodiment, the trench isolation structure is formed in a memory integrated circuit.

In an additional embodiment, an isolation trench is formed according to a method where one or more layers on the semiconductor substrate and the semiconductor substrate is first etched. Next, a spacer is deposited onto the etched semiconductor substrate and the spacer is used to perform a second etch which produces a shallow trench isolation structure as described herein.

### BRIEF DESCRIPTION OF THE DRAWINGS

FIG. 1 illustrates an embodiment cross section of a resulting structure after performance of an etch method according to the present disclosure.

FIG. 2 illustrates an embodiment cross section of a resulting structure after performance of an etch method according to the present disclosure.

FIG. 3 is a schematic cross sectional view of a representative substrate undergoing the formation of a shallow trench isolation structure, performed in accordance with a method embodiment of the present invention.

FIG. 4 is a cross sectional view of the representative substrate of FIG. 3 and at a stage of processing subsequent to that shown in FIG. 3.

FIG. 5 is a cross sectional view of the representative substrate of FIG. 3 and at a stage of processing subsequent to that shown in FIG. 4.

FIG. 6 is a cross sectional view of the representative substrate of FIG. 3 and at a stage of processing subsequent to that shown in FIG. 5.

FIG. 7 illustrates a general diagram of a plasma generation device suitable for use with embodiments of the present disclosure.

FIG. 8 is a schematic cross-sectional view of a portion of a conventional memory DRAM device with a shallow trench isolation structure formed in accordance with embodiments of the present disclosure.

FIG. 9 is an illustration of a computer system having a memory cell with a shallow trench isolation structure formed in accordance with embodiments of the present disclosure.

### DETAILED DESCRIPTION OF THE INVENTION

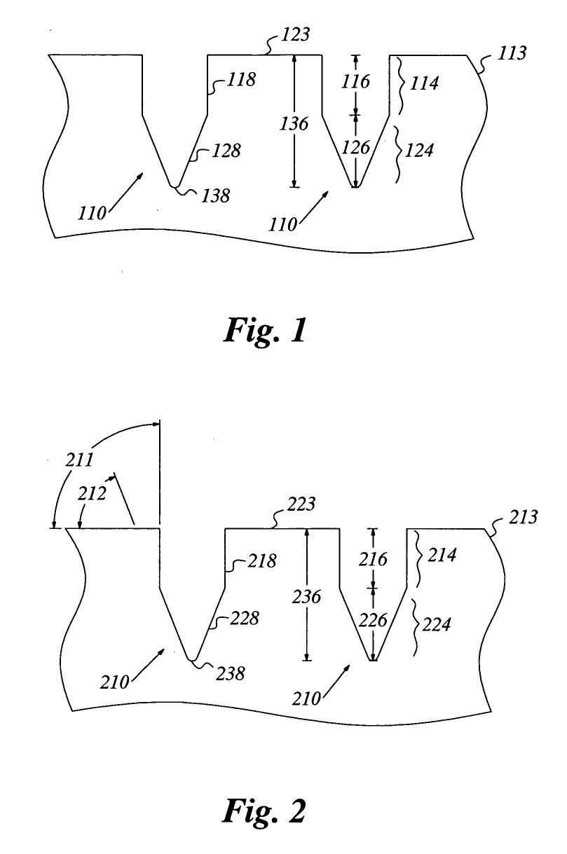

The Figures herein follow a numbering convention in which the first digit or digits correspond to the drawing Figure number and the remaining digits identify an element or component in the drawing. Similar elements or components between different Figures may be identified by the use of similar digits. For example, 110 may reference element “10” in FIG. 1, and a similar element may be referenced as 210 in FIG. 2. It should also be apparent that the scaling on the figures does not represent precise dimensions of the various elements illustrated herein.

Reference is made to various specific embodiments in which the invention may be practiced herein. These embodiments are described with sufficient detail to enable those skilled in the art to practice the invention, and it is to be understood that other embodiments may be employed, and that structural, logical, and electrical changes may be made.

As used herein, the term “semiconductor substrate” or “semiconductive substrate” is defined to mean any construction comprising semiconductive material, including, but not limited to bulk semiconductive materials such as a semiconductive wafer (either alone or in assemblies comprising other materials thereon), and semiconductive material layers (either alone or in assemblies comprising other materials). As used herein, the term “substrate” refers to any supporting structure, including, but not limited to, the semiconductive substrates described herein. As used herein, the term “layer” encompasses both the singular and the plural unless otherwise indicated.

Also, the term “substrate” used herein may include any semiconductor-based structure that has an exposed silicon surface. Structure must be understood to include silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium-arsenide. When reference is made to a substrate herein, previous process steps have been utilized to form regions or junctions in the base semiconductor or foundation.

Although shallow trench isolation (STI) structures have been used extensively to isolate circuits, dielectric deposition and trench fill has proven difficult due to the development of voids. Typically, dielectric material is deposited in trenches using chemical vapor deposition (CVD) or high-density plasma chemical vapor deposition (HDP-CVD). However, during deposition, dielectric material will collect on the corners of the trenches, and overhangs will form at the corners. These overhangs typically grow together faster than the trench is filled, and a void in the dielectric material filling the gap is created. Many techniques have been utilized in attempts to solve the trench fill problem.

The present disclosure provides a trench isolation structure and a method for creating a trench isolation structure with a first trench isolation portion and a second trench isolation portion which has an angled surface, where the volume of the first trench isolation portion is greater than the second trench isolation portion. Since the volume of the second trench isolation portion is smaller than the first trench isolation portion, the trench bottom will fill faster than a traditional, rectangular shallow trench isolation structure. As the second trench isolation portion fills, the dielectric material will more quickly reach the first trench isolation portion and the surface of the semiconductor substrate, eliminating any voids that may potentially have been beginning to form due to corner overhang of dielectric material.

FIG. 1 shows shallow trench isolation structure 110 formed in a semiconductor substrate 113 in accordance with one embodiment of the present disclosure. The trench isolation structure 110 includes a first isolation trench portion 114 and a second isolation trench portion 124, where the second isolation trench portion 124 volume is less than the first isolation trench portion 114 volume. The first isolation trench portion 114 has a first sidewall 118 that is perpendicular or nearly perpendicular to the surface 123 of the semiconductor substrate 113. The second isolation trench portion 124 has a second sidewall 128 that is angled obliquely with respect to the surface 123 of the substrate 113. In one embodiment, the first isolation trench portion has a depth 116 ranging from approximately five hundred (500) to approximately one thousand (1,000) angstroms (Å). Also, the trench isolation structure can have a total depth 136 from approximately two thousand (2,000) to approximately two thousand five hundred (2,500) Å.

In an additional embodiment, the second sidewall 128 tapers to a rounded point 138 in the center of the shallow trench isolation structure 110. The shallow trench isolation structure also can contain a dielectric material (not shown), for example, a high density plasma oxide such as silicon dioxide. Alternatively, the shallow trench isolation structure can contain an insulating layer (not shown), for example silicon nitride, between the dielectric material and the substrate 113.

FIG. 2 shows another embodiment of a trench isolation structure formed in a semiconductor. The first isolation trench portion 214 has a first sidewall 218 intersecting the surface 223 of the semiconductor 213 at a first angle 211 of approximately ninety (90) degrees. The second isolation trench portion 224, then, is within and extends below the first isolation trench portion 214, and includes a second sidewall 228 intersecting the first sidewall 218 at a second angle 212 with respect to the surface 223 that is less than the first angle 211.

In one embodiment, the second angle 212 ranges from approximately fifty (50) degrees to approximately eighty-five (85) degrees, and tapers to a rounded point 238 in the center of the trench isolation structure 210.

In one embodiment the first isolation trench portion 214 includes a first depth 216 that ranges from about twenty (20) percent to about fifty (50) percent of the total trench depth 236 of the trench isolation structure 210. Also, the total trench depth 236 can range from approximately two thousand (2,000) to approximately two thousand five hundred (2,500) Å. In one additional embodiment, the trench isolation structure 210 can be formed in a memory integrated circuit.

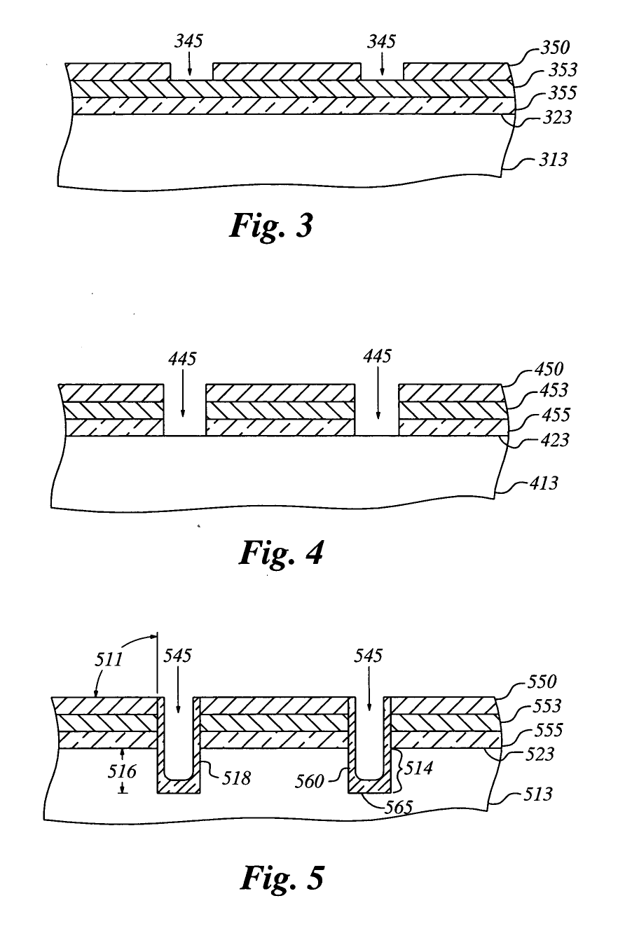

FIG. 3 depicts a portion of a semiconductor substrate 313 with a patterned mask layer 350 already formed on it. An opening 345 is formed in patterned mask layer 350 by any suitable method. For example, if patterned mask layer 350 is made of photoresist, then opening 345 may be formed by any standard photolithography technique.

In some embodiments, patterned mask layer 350 is composed of a hard mask material, such as silicon nitride, silicon oxide, or carbon. In such embodiments, the patterned mask layer 350 may be formed by first depositing a blanket layer of hard mask material, then forming a patterned layer of photoresist above the hard mask material, and transferring the pattern from the photoresist to the hard mask material. Methods and materials for forming suitable patterned mask layers 350 will be apparent to those skilled in the art. Further, although only a portion of substrate 313 is depicted in FIGS. 1-8, it should be understood that the present disclosure contemplates simultaneous creation of multiple shallow trench isolation features at various locations on a substrate.

FIGS. 3-6 show the method of forming shallow trench isolation structure 210 (in FIG. 2) of the present disclosure. As discussed herein, as shown in FIG. 3, the trench isolation structure 210 (in FIG. 2) is created by forming one or more layers on the semiconductor surface. For example, an oxide layer 355 on the semiconductor surface 323, and an additional layer 353 on the oxide layer 355 may be formed on the semiconductor substrate, however, more or less layers of differing materials may also be formed, as appreciated by those skilled in the art. In one embodiment the additional layer 353 is provided for conduction purposes, in a further embodiment, the additional layer 353 is a polymer. In addition, a masking layer 350 can be formed on top of the additional layer 353. Openings 345 are formed in the masking layer 350 by means apparent to those skilled in the art.

FIG. 4 shows a next sequence of processing steps in accordance with an embodiment of a shallow isolation structure according to the present disclosure. In one embodiment, the method includes a dry etch to form openings in the one or more layers. In one embodiment, the one or more layers are dry etched using a gas chemistry of helium (He) and fluorocarbon gases, such as, by way of example, carbon tetraflouride (CF₄), carbon trifluoride (CHF₃), and/or difluoromethane (CH₂F₂), or the like. A gas chemistry of hydrogen bromide (HBr) and chlorine (Cl₂) may also be used.

In one embodiment, to form the first isolation trench portion 214 (in FIG. 2) the semiconductor material is dry etched using a first gas chemistry of HBr and Cl₂. In one embodiment, the plasma etch is performed using a first gas chemistry of HBr and Cl₂ in a ratio equal to about 2:1. As one with ordinary skill in the art will appreciate, a broad variety of implementations are possible using different etch gas compositions.

In one embodiment, the first isolation trench portion 514 has a first sidewall 518 perpendicular or nearly perpendicular to the surface of the semiconductor substrate 523, as shown in FIG. 5. In other words, the first isolation portion 514 has a first sidewall 518 that is vertical. In one embodiment, the first isolation trench portion 514 has a depth 516 ranging from approximately five hundred (500) to approximately one thousand (1,000) Å.

Once the first isolation trench portion 514 is formed, a polymer layer 560 is formed on the sidewall 518 and the bottom portion 565 of the first isolation trench portion 514 using a second gas chemistry of CH₂F₂ and oxygen (O₂). In one embodiment, the ratio of CH₂F₂ to O₂ is about 4:1. The polymer layer 560 is formed by a deposition on the first isolation trench portion 514 by a dry etch using the second gas chemistry. The sidewall 518 polymer serves as a spacer by confining the next etching step into a smaller area, which forms a smaller second isolation trench portion within and extending below the first isolation trench portion.

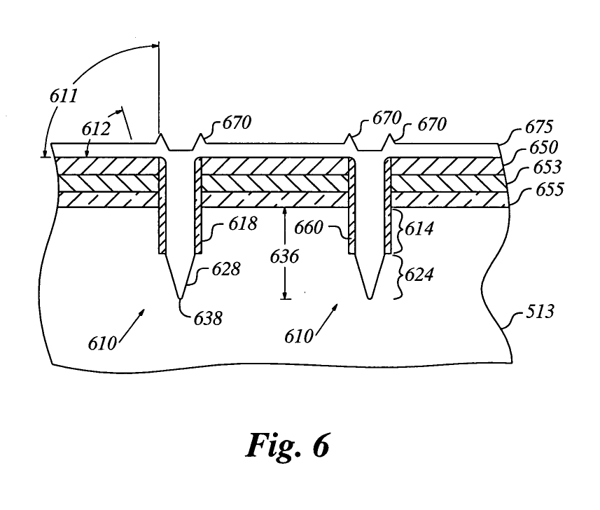

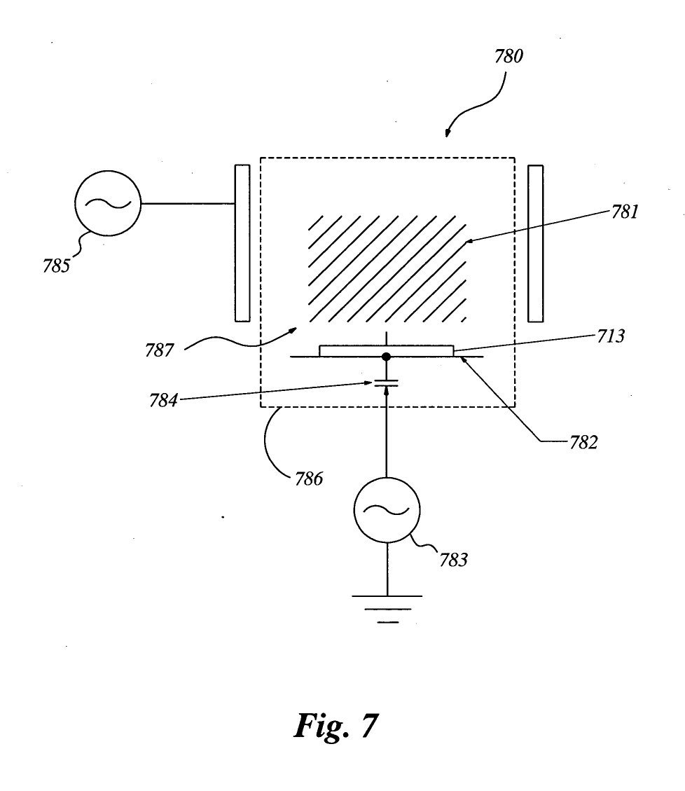

As shown in FIG. 6, to form the second isolation trench portion a dry, anisotropic etch is performed using a third gas chemistry of CH₂F₂, HBr, and Cl₂. The anisotropic etch allows the process to etch through the polymer layer 660 on the bottom portion 665 of the first isolation trench portion 614 while leaving the polymer layer 660 on the sidewall 618, the spacer, intact. Once the polymer layer 660 on the bottom is etched through, the dry etch continues into the semiconductive substrate 613 forming the second isolation trench portion 624 with a second sidewall 628 angled obliquely with respect to the surface of the semiconductor substrate. In one embodiment, the second sidewall 628 tapers to a rounded point 638 in the center of the shallow isolation trench structure 610. In an additional embodiment, the second isolation trench portion 624 is formed with a second angle 612 between approximately fifty (50) and approximately eighty-five (85) degrees. In one embodiment, the ratio of CH₂F₂ to HBr to Cl₂ is about 1:8:1. As will be appreciated, the ratio of CH₂F₂ to HBr to Cl₂ can be adjusted to enable differing second sidewall angles 612 and subsequent total trench depths 636.

Following etching of the first 614 and second 624 isolation trench portions, the one or more additional layers and the spacer 660 may be stripped using conventional means known to those skilled in the art, resulting in the shallow isolation structure of the present disclosure, as shown in FIGS. 1 and 2.

Also shown in FIG. 6, in one embodiment, the shallow trench isolation structure is filled with high density plasma (HDP) oxide, a material which has a high ability to effectively fill narrow trenches. During the trench-fill process, the dielectric material may form small hills 670 around the trench opening; however, conventional chemical-mechanical polishing may be used to planarize the resulting structure.

Alternatively, an insulating layer (not shown) may be formed on the first and second sidewalls 618, 628 prior to filling the shallow trench isolation structure 610 with the dielectric 675. In one embodiment, the insulating layer is formed by oxidizing the trench walls 618, 628. In another embodiment, the insulating layer is formed by depositing a thin oxide layer underneath an additional layer of silicon nitride. In any case, the insulating layer aids in smoothing out the corners in the shallow isolation trench structure 610 and reducing the amount of stress in the dielectric 675 used later to fill the trench.

In most shallow trench isolation structure etch methods, if a spacer is formed it is done by an ex-situ process using either chemical vapor deposition (CVD) or plasma vapor deposition (PVD). Generally, this method requires the use of three chambers. For example, in the first chamber the one or more layers are etched and the semiconductor substrate is etched. In the second chamber, the spacer is formed using either CVD or PVD. In the third chamber, the spacer and the semiconductor substrate are further etched. By contrast, in this disclosure the spacer is formed by a dry etch, eliminating the need for an ex-situ process, and allowing the entire etch method to be performed in one chamber.

FIG. 7 generally shows an illustrative etch reactor 780 for performing etching. It should be recognized that this is an illustrative diagram representative of an entire system even though only several components of the system are shown. Various systems incorporating many elements in various configurations may be utilized. To generate plasma 781, the different gas mixtures according to the present disclosure are provided to the illustrative plasma generator 780.

The illustrative etch reactor 780 includes a powered electrode 782 connected to an RF bias source 783 via capacitance 784 upon which a semiconductor substrate having a layers to be etched is placed. Further, an RF source 785 is connected to elements, e.g., coils, for generating the plasma 781 in chamber 786. Ion sheath 787 is formed between the plasma 781 and the powered electrode 782. With the semiconductor substrate 713 positioned within the illustrative plasma generation apparatus 780, one or more layers on the semiconductor substrate are etched using a first gas chemistry of HBr and Cl₂ or He and CF4. The semiconductive substrate is then etched using a second gas chemistry of HBr and Cl₂, forming the first isolation trench portion within the semiconductive material. Once the first isolation trench portion is formed, a polymer layer is formed on the first isolation trench portion sidewall and bottom by a dry etch using a third gas chemistry of CH₂F₂ and O₂. Finally, the polymer layer is anisotropically etched on the bottom portion of the first isolation trench portion within the plasma etcher effective to expose the semiconductor substrate and further etched into the semiconductive substrate using a fourth gas chemistry of CH₂F₂, HBr, and Cl₂. The four-step process is performed in a single plasma etch chamber, resulting in the structure of FIG. 7. The power source 785 utilized may be any suitable power source including an RF generator, a microwave generator, etc. It will be readily apparent that any plasma etching system may be used.

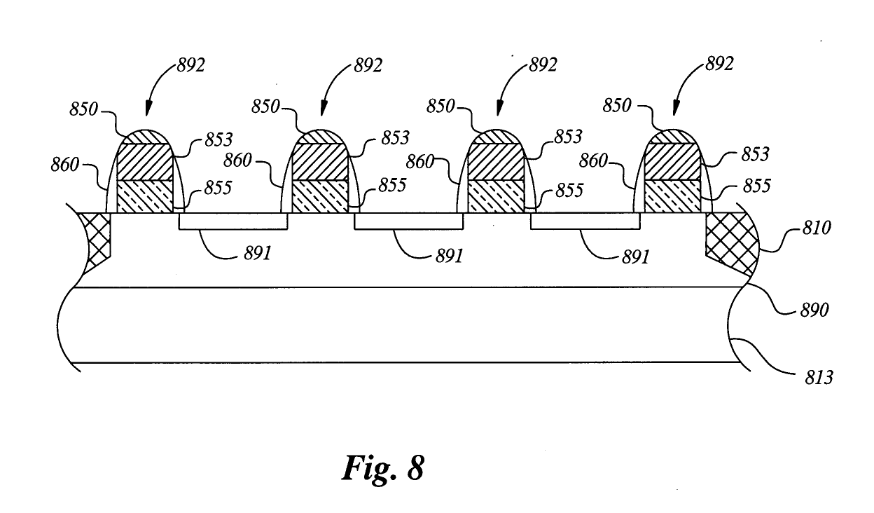

In addition to the formation of shallow trench structures for isolation, such as structure 110 of FIG. 1, and structure 210 of FIG. 2, further steps to create a functional memory cell may be carried out in accordance with conventional integrated circuit (IC) fabrication processes. For example, FIG. 8 depicts a conventional memory cell construction for a dynamic random access memory (DRAM) at an intermediate stage of the fabrication at which the cell access transistors are formed, and in which an STI structure, such as structure 210 of FIG. 2, has been formed in substrate 813 according to a method of the present disclosure.

As shown in FIG. 8, a pair of memory cells having respective access transistors is formed within a p-well 890 of substrate 813. The transistors of the cell are surrounded by the shallow trench isolation region 810 that provides electrical and physical isolation. N-type active regions 891 are provided in the doped p-well 890 of substrate 813 (for NMOS transistors) and the pair of access transistors have respective gate stacks 892, each of which includes an oxide layer 855, a conductive layer 853, such as polysilicon, nitride spacers 860, and a nitride cap 850. Next, as known in the art, polysilicon plugs, capacitors, metal contacts and bit lines could be formed in, or on, one or more insulating layers provided over the FIG. 8 structure using well-known techniques to produce operative DRAM cells.

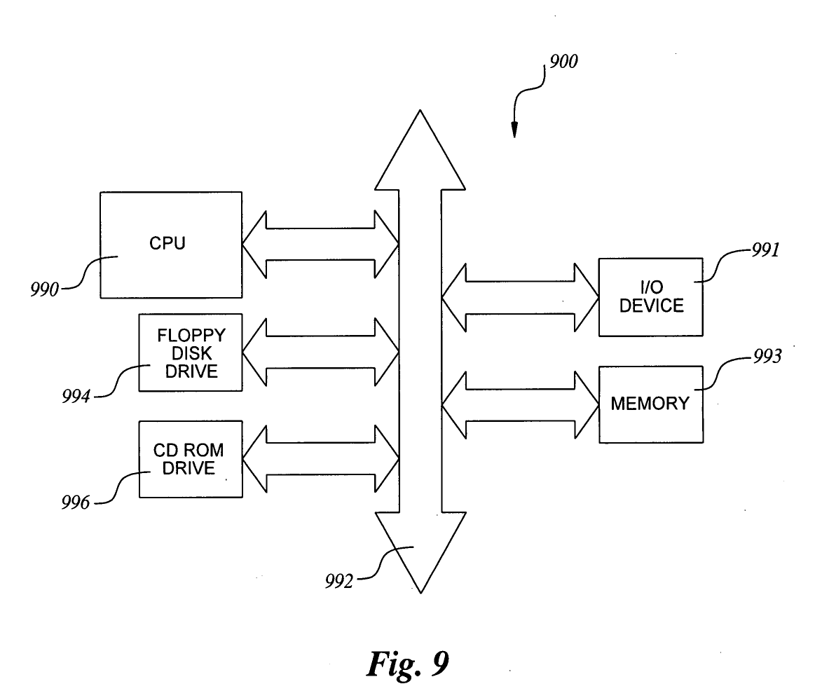

The memory cells of FIG. 8, employing the shallow trench isolation region 810 fabricated in accordance with the present invention, could further be part of a typical processor based system, which is illustrated generally at 900 in FIG. 9. A processor system, such as a computer system, generally comprises a central processing unit (CPU) 990, such as a microprocessor, which communicates with an input/output (I/O) device 991 over a bus 992. A memory 993, having at least one shallow trench isolation region fabricated according to the present disclosure, also communicates with the CPU 990 over bus 992. In addition, the CPU 990 may itself contain regions isolated with at least one shallow trench isolation region fabricated according to the present invention.

In the case of a computer system, the processor system may include additional peripheral devices such as a floppy disk drive 994, and a compact disk (CD) ROM drive 996 which also communicate with CPU 990 over the bus 992. Memory 993 is preferably constructed as an integrated circuit, which includes shallow trench isolation structures formed as described herein with respect to FIGS. 1-7. The memory 993 may be combined with a processor, such as a CPU, digital signal processor or microprocessor, with or without memory storage, in a single integrated circuit chip.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

We claim:

1. A semiconductor device, comprising:
a substrate; and
a shallow trench isolation structure on the substrate, the shallow trench isolation structure comprising:
a first isolation trench portion with a first sidewall that is perpendicular or nearly perpendicular to a surface of the substrate; and
a second isolation trench portion with a second sidewall that is angled obliquely with respect to the surface of the substrate, wherein the second isolation trench portion has a second volume that is less than a first volume of the first isolation trench portion, within the substrate.

2. The semiconductor device of claim 1, wherein the first isolation trench portion has a depth ranging from approximately five hundred (500) to approximately one thousand (1,000) angstroms (Å).

3. The semiconductor device of claim 2, wherein the shallow trench isolation structure has a total depth ranging from approximately two thousand (2,000) to approximately two thousand five hundred (2,500) Å.

4. The semiconductor device of claim 1, wherein the second sidewall tapers to a rounded point in the center of the shallow trench isolation structure.

5. The semiconductor device of claim 1, wherein the shallow trench isolation structure contains a dielectric material therein.

6. The semiconductor device of claim 5, wherein the dielectric material is a high density plasma oxide.

7. The semiconductor device of claim 5, wherein the shallow trench isolation structure further contains an insulating layer between the dielectric material and the substrate.

8. The semiconductor device of claim 1, wherein the second isolation trench portion is within and extending below the first isolation trench portion.

9. A trench isolation structure formed in a semiconductor comprising:
a first isolation trench portion having a first sidewall intersecting a surface of the semiconductor at a first angle of approximately ninety (90) degrees; and
a second isolation trench portion within and extending below the first isolation trench portion, including a second sidewall intersecting the first sidewall at a second angle with respect to the surface that is less than the first angle.

10. The trench isolation structure of claim 9, wherein the second angle ranges from approximately fifty (50) degrees to approximately eighty-five (85) degrees.

11. The trench isolation structure of claim 10, wherein the second sidewall tapers to a rounded point in the center of the trench isolation structure.

12. The trench isolation structure of claim 9, wherein the first isolation trench portion further comprises a first depth ranging from about twenty (20) percent to about fifty (50) percent of a total trench depth of the trench isolation structure.

13. The trench isolation structure of claim 9, wherein the first isolation trench portion further comprises a first depth ranging from approximately five hundred (500) to approximately one thousand (1,000) Å.

14. The trench isolation structure of claim 9, wherein the trench isolation structure has a total trench depth ranging from approximately two thousand (2,000) to approximately two thousand five hundred (2,500) Å.

15. The trench isolation structure of claim 9, wherein the trench isolation structure is formed in a memory integrated circuit.

16. An isolation trench structure in a semiconductor substrate formed according to a method, comprising:
first etching through one or more layers on the semiconductor substrate and into the semiconductor substrate;
depositing a spacer onto the etched semiconductor substrate; and
using the spacer to perform a second etch wherein the first etch and the second etch produce a shallow trench isolation structure comprising;
a first isolation trench portion with a first sidewall that is perpendicular or nearly perpendicular to a surface of the semiconductor substrate; and
a second isolation trench portion with a second sidewall angled obliquely with respect to the surface of the semiconductor substrate, wherein the second isolation trench portion has a second volume that is less than a first volume of the first isolation trench portion.

17. The structure of claim 16, wherein the first etch is performed using a first gas chemistry comprising hydrogen bromide (HBr) and chlorine (Cl₂), the first etch into the semiconductor substrate forming the first isolation trench portion.

18. The structure of claim 16, wherein the spacer is formed using a second gas chemistry comprising difluoromethane (CH₂F₂) and oxygen (O₂).

19. The structure of claim 16, wherein the second etch is performed using a third gas chemistry comprising difluoromethane (CH₂F₂), hydrogen bromide (HBr), and chlorine (Cl₂), the second etch into the semiconductor substrate forming the second isolation trench portion.

20. The structure of claim 19, wherein the second isolation trench portion is within and extending below the first isolation trench portion.

21. The structure of claim 19, wherein forming the second isolation trench portion includes forming the second sidewall at an angle relative to the surface of the semiconductor substrate of between approximately fifty (50) and approximately eighty-five (85) degrees and the second sidewall tapers to a rounded point in the center of the shallow trench isolation structure.

22. The structure of claim 16, wherein the first gas chemistry comprises hydrogen bromide (HBr) and chlorine (Cl₂) at a ratio of about 2:1.

23. The structure of claim 16, wherein the second gas chemistry comprises difluoromethane (CH₂F₂) and oxygen (O₂) at a ratio of about 4:1.

24. The structure of claim 16, wherein the third gas chemistry comprises difluoromethane (CH₂F₂), hydrogen bromide (HBr), and chlorine (Cl₂) in a ratio of about 1:8:1.

25. The structure of claim 16, wherein the first isolation trench portion further comprises a first depth ranging from about twenty (20) percent to about fifty (50) percent of a total trench depth.

26. A trench isolation structure formed in a semiconductor comprising:
a first isolation trench portion having a first sidewall intersecting a surface of the semiconductor at a first angle of approximately ninety (90) degrees; and
a second isolation trench portion formed within and extending below the first isolation trench portion, including a second sidewall intersecting the first sidewall at a second angle with respect to the surface that is less than the first angle by forming a polymer layer and using the polymer layer as a spacer to create the second isolation trench portion having a second volume that is less than a first volume of the first isolation trench portion.

27. The trench isolation structure of claim 26, wherein the polymer layer is formed using a gas chemistry comprising difluoromethane (CH₂F₂) and oxygen (O₂) in a ratio of about 4:1.

28. The trench isolation structure of claim 26, wherein the second angle ranges from approximately fifty (50) to approximately eighty-five (85) degrees.

29. The trench isolation structure of claim 28, wherein the second sidewall tapers to a rounded point in the center of the isolation structure.

30. The trench isolation structure of claim 26, wherein the first isolation trench portion further comprises a first depth ranging from about twenty (20) percent to about fifty (50) percent of a total trench depth of the trench isolation structure.

31. A method for operating an etch reactor, comprising:
supplying a first gas chemistry to the etch reactor to etch through one or more layers on a semiconductor substrate and exposing the semiconductor substrate;
supplying a second gas chemistry to the etch reactor to etch into the semiconductor substrate to form a first isolation trench portion within the semiconductor substrate, the first isolation trench portion having a first sidewall with a first angle with respect to a surface of the semiconductor substrate;
supplying a third gas chemistry to the etch reactor to form a polymer layer on the first sidewall and a bottom portion of the first isolation trench portion; and
supplying a fourth gas chemistry to the etch reactor to etch through the polymer layer on the bottom portion of the first isolation trench portion to etch into the semiconductor substrate and to form a second isolation trench portion having a second sidewall intersecting the first sidewall at a second angle with respect to the upper surface that is less than the first angle.

32. The method of claim 31, wherein the first gas chemistry comprises helium (He) and carbon tetraflouride (CF₄) or hydrogen bromide (HBr) and chlorine (Cl₂).

33. The method of claim 31, wherein the second gas chemistry comprises hydrogen bromide (HBr) and chlorine (Cl₂).

34. The method of claim 31, wherein the third gas chemistry comprises difluoromethane (CH₂F₂) and oxygen (O₂).

35. The method of claim 31, wherein the fourth gas chemistry comprises difluoromethane (CH₂F₂), hydrogen bromide (HBr), and chlorine (Cl₂).

36. A processor-based system, comprising:
a processor; and
a memory device coupled to the processor, the memory device including a memory structure, wherein the memory structure includes a shallow trench isolation structure having:
a substrate;
a first isolation trench portion with a first sidewall that is perpendicular or nearly perpendicular to a surface of the substrate; and
a second isolation trench portion with a second sidewall that is angled with respect to the surface of the substrate, wherein the second isolation trench portion has a second volume that is less than a first volume of the first isolation trench portion, within the substrate.

37. The processor-based system of claim 36, wherein the memory device is a dynamic random access memory (DRAM) device.

38. The processor-based system of claim 36, wherein the second isolation trench portion is within and extends below the first isolation trench portion.
